(19) United States
(12) Patent Application Publication
(10) Pub. No.: US 2016/0195589 A1
(43) Pub. Date: Jul. 7, 2016

(54) DEGRADATION DIAGNOSIS SYSTEM AND DEGRADATION DIAGNOSIS METHOD FOR SECONDARY BATTERY

(71) Applicant: KABUSHIKI KAISHA TOSHIBA, Minato-ku (JP)

(72) Inventors: Yuki Hanyu, Kawasaki (JP); Takahiro Yamamoto, Fuchu (JP)

(73) Assignee: KABUSHIKI KAISHA TOSHIBA, Minato-ku (JP)

(21) Appl. No.: 15/066,643

(22) Filed: Mar. 10, 2016

Related U.S. Application Data
(63) Continuation of application No. PCT/JP2014/073684, filed on Sep. 8, 2014.

(30) Foreign Application Priority Data
Sep. 19, 2013 (JP) 2013-194608

(51) Int. Cl. G01R 31/36

(52) U.S. Cl. CPC G01R 31/3679; G01R 31/3651

(57) ABSTRACT

A degradation diagnosis system includes: a feature amount calculator and a diagnoser. The calculator reads a relation between: a ratio between a variation of a voltage of a secondary battery and a variation of an electric charge of the secondary battery; and the voltage or the electric charge of the secondary battery. The calculator identifies the voltage or the electric charge whose relation with the ratio satisfies a predefined condition and calculates a feature amount of the secondary battery. The diagnoser diagnoses degradation of the secondary battery, based on the feature amount. The calculator calculates the feature amount, based on a relation between: an integrated value within a range where a voltage or an electric charge is larger than the identified voltage or electric charge; and an integrated value within a range where the voltage or the electric charge is smaller, in a curve represented by the relational data.

### CROSS REFERENCE TO RELATED APPLICATIONS

This application is a Continuation of International Application No. PCT/JP2014/073684, filed on Sep. 8, 2014, the entire contents of which is hereby incorporated by reference.

### FIELD

Embodiments of the invention relate to a degradation diagnosis system and a degradation diagnosis method for a secondary battery.

### BACKGROUND

Conventionally, capacitance degradation of a secondary battery has been diagnosed by comparing a detailed use history of charge and discharge of the secondary battery with charge and discharge characteristics associated with its capacitance degradation. However, as it is difficult to obtain the use history of the secondary battery, the degradation diagnosis has been often made by using limited experimental data. Also, a conventional degradation diagnosis method has a problem that the diagnostic accuracy of a degradation state lowers when diagnosis is made based on the limited experimental data.

Furthermore, when a degradation state of a secondary battery including an electrode composed of a plurality of active materials is diagnosed, it has been difficult to accurately diagnose the degradation state of the secondary battery because, even if an internal resistance or a capacitance value can be uniquely estimated, a degradation state may occur that cannot be known only from the internal resistance and the capacitance value and an estimated error is large.

### BRIEF DESCRIPTION OF THE DRAWINGS

FIG. 1 is a block diagram showing a degradation diagnosis system according to a first embodiment;

FIG. 2 is a flowchart showing operation of the degradation diagnosis system;

FIG. 3 is a graph showing a charge curve created by an inspection device;

FIG. 4 is a view showing a differential curve and a feature amount created from the charge curve in FIG. 3;

FIG. 5 is a process flowchart of a degradation diagnosis in the first embodiment;

FIG. 6 is a view showing a degradation characteristic of a voltage “V_{LMO}”;

FIG. 7 is a view showing a degradation characteristic of an electric charge ratio “Q_{NCA}/Q_{LMO}”;

FIG. 8 is a block diagram showing a degradation diagnosis system according to a second embodiment;

FIG. 9 is a view showing a feature amount according to the second embodiment;

FIG. 10 is a process flowchart of a degradation diagnosis according to the second embodiment;

FIG. 11 is a view showing a degradation characteristic of a voltage “V_{R}”;

FIG. 12 is a view showing a relation between a temperature characteristic and capacitance degradation of a secondary battery;

FIG. 13 is a view showing the temperature characteristic measured by the inspection device;

FIG. 14 is a view showing a degradation characteristic of a voltage “V_{T}”;

FIG. 15 is a process flowchart in which the inspection device creates a charge and discharge curve;

FIG. 16 is a view showing a charge and discharge measurement pattern created by the inspection device according to a pattern 1;

FIG. 17 is a view showing a charge and discharge measurement pattern created by the inspection device according to a pattern 2; and

FIG. 18 is a view showing a charge and discharge measurement pattern created by the inspection device according to a pattern 3.

### DETAILED DESCRIPTION

According to one embodiment, a degradation diagnosis system includes: a feature amount calculator and a degradation diagnose.

The feature amount calculator reads in relational data including a relation between: a ratio between a variation of a voltage of a secondary battery and a variation of an electric charge of the secondary battery; and the voltage or the electric charge of the secondary battery.

The feature amount calculator identifies the voltage or the electric charge in which a relation between the voltage or the electric charge and the ratio satisfies a predefined condition and calculates a feature amount of the secondary battery by using the identified voltage or the identified electric charge as a reference on basis of the relational data.

The degradation diagnoser diagnoses degradation of the secondary battery, based on the feature amount.

The feature amount calculator calculates the feature amount, based on a relation between: an integrated value within a range where a voltage or an electric charge is larger than the identified voltage or the identified electric charge; and an integrated value within a range where the voltage or the electric charge is smaller than the identified voltage or the identified electric charge, in a curve represented by the relational data.

Embodiments of the invention will be described below with reference to the drawings.

### First Embodiment

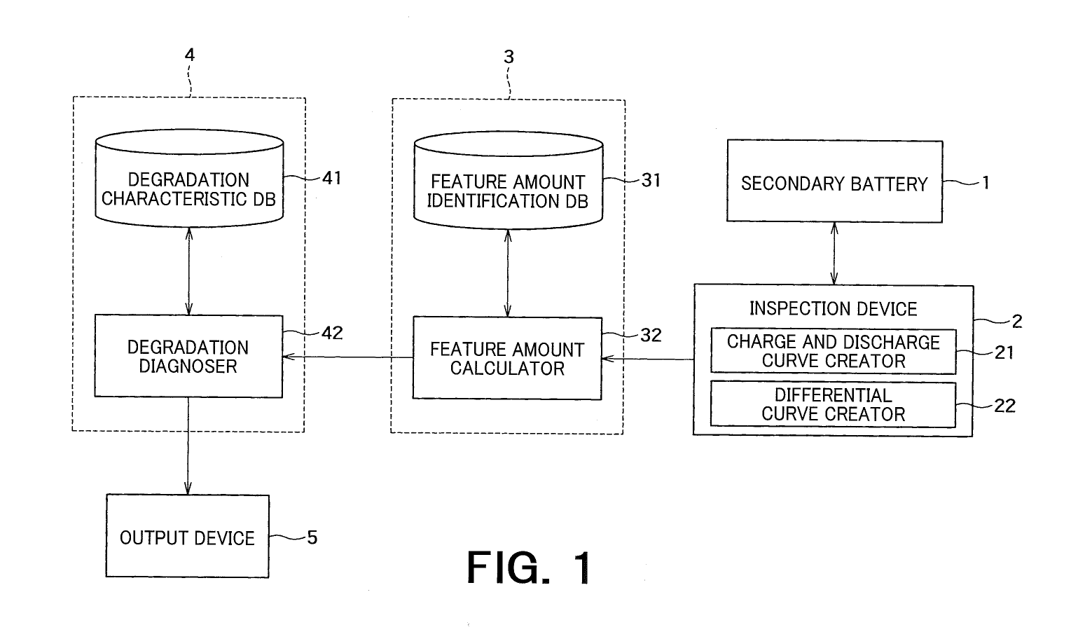

FIG. 1 is a block diagram showing a degradation diagnosis system according to a first embodiment. This degradation diagnosis system is a system to diagnose degradation of a secondary battery. The degradation diagnosis system diagnoses the degradation of a secondary battery to be diagnosed by comparing a feature amount calculated from charge and discharge characteristics of the secondary battery with a preliminarily prepared degradation characteristic of the relevant secondary battery. The degradation diagnosis system includes a secondary battery 1 to be diagnosed, an inspection device 2 to measure the charge and discharge characteristics of the secondary battery 1, a feature amount calculation device 3 to calculate a feature amount based on the measurement result, a degradation diagnosis processor 4 to diagnose degradation of the secondary battery 1 based on the feature amount and an output device 5 to output the diagnosis result.

The secondary battery 1 is a reusable storage battery through charge and discharge and electrically connected to the degradation diagnosis system as a diagnostic object. The degradation diagnosis system can diagnose capacitance degradation of any types of secondary battery, such as a lithium ion battery, a lithium ion polymer battery, a lead storage battery, a nickel cadmium battery and a nickel-metal hydride battery. The secondary battery 1 to be diagnosed may be a secondary battery composed of a single cell, an assembled battery composed of a plurality of cells or a battery pack composed of a plurality of assembled batteries.

The inspection device 2 includes a charge and discharge curve creator 21 to create a charge and discharge curve and a differential curve creator 22 to create a differential curve based on the charge and discharge curve. The charge and discharge curve creator 21 measures the charge and discharge characteristics such as a voltage “V” and an electric charge “Q” and characteristic values such as a resistance value “R”, a temperature “T” and a width “W” of the secondary battery 1, and creates at least one of a charge curve and a discharge curve (hereafter, these are collectively called “a charge and discharge curve”). The charge and discharge curve represents the charge and discharge characteristics of the secondary battery 1 as a function of the voltage “V” and the electric charge “Q” (or a time). That is, the charge curve represents a relation between the voltage “V” across terminals of the secondary battery 1 and the electric charge “Q” charged in the secondary battery (or the elapsed time) when the secondary battery 1 is charged at a constant charge current rate. The discharge curve represents a relation between the voltage “V” across the terminals of the secondary battery and the electric charge “Q” (or, the elapsed time) discharged from the secondary battery when the secondary battery 1 is discharged at a constant discharge current rate. The charge and discharge curve is represented, for example, by the voltage “V” on a vertical axis and the electric charge “Q” on a horizontal axis, and varies according to capacitance degradation of the secondary battery 1.

The charge and discharge curve creator 21 is one example of a charge and discharge data creator to acquire at least one of charge data and discharge data, based on the measured voltage by the inspection device 2. The charge data and the discharge data is, as one example, data to represent a relation between the voltage and the electric charge or a relation between the voltage and the time.

The differential curve creator 22 creates a differential curve based on the measured voltage “V” and electric charge “Q” (charge and discharge curve) of the secondary battery 1. The differential curve represents, as a function, a relation between the voltage “V” and “dQ/dV” that is a ratio of a variation “dQ” of the electric charge “Q” to a variation “dV” of the voltage “V”. The differential curve is represented, as one example, by a differential value “dQ/dV” on a vertical axis and the voltage “V” on a horizontal axis. Both the variation “dQ” and the variation “dV” are minutely small, and a differential coefficient “dQ/dV” represents a slope which is derived from the charge and discharge curve. The shape of the differential curve varies correspondingly to deformation of the charge and discharge curve. When, as the charge and discharge curve, data about the relation between the voltage and the time is input, the differential curve may be created by using information about a charge rate.

As a modification, a differential curve may be created by representing the differential value “dV/dQ” on the vertical axis and the electric charge “Q” on the horizontal axis. In this case, in the description of this embodiment and processes hereafter described, if an electric charge is substituted for the previous voltage on the horizontal axis of the “dQ/dV” curve and a voltage to be compared with the relevant voltage, the similar discussion holds true.

The differential curve creator 22 is one example of a relational data creator to create relational data representing a relation of a ratio between the variation of the voltage of the secondary battery and the variation of the electric charge of the secondary battery to the voltage of the secondary battery, based on at least one of the charge data and the discharge data created by the above charge and discharge data creator.

The inspection device 2 inputs information such as about the charge and discharge curve (the charge and discharge characteristics) and the differential curve of the secondary battery 1 into the feature amount calculation device 3. Note that the charge and discharge curve creator 21 and the differential curve creator 22 may be provided in the inspection device 2, or a separate device from the inspection device 2.

The feature amount calculation device 3 calculates a feature amount of the secondary battery 1, based on the information input by the inspection device 2. The feature amount calculation device 3 includes a feature amount identification DB (database) 31 on which an algorithm (calculation method) to calculate the feature amount is stored, and a feature amount calculator 32 to calculate the feature amount.

The feature amount identification DB 31 stores the algorithm to calculate the feature amount from the information input by the inspection device 2, such as the differential curve. The algorithm is stored correspondingly to types of the secondary battery 1, charge and discharge conditions (such as a current rate “1 C”) and a feature amount to be calculated.

The feature amount calculator 32 calculates one or a plurality of feature amounts by applying the algorithm retrieved from the feature amount identification DB 31 to the differential curve input by the inspection device 2. Here, the feature amounts are a physical quantity such as the voltage and the electric charge calculated or derived from the differential curve, and a dimensionless quantity such as an electric charge ratio. The feature amounts vary correspondingly to capacitance degradation of the secondary battery 1 and the degree of the variation is different depending on each of the feature amounts. If a positive electrode and a negative electrode of the secondary battery 1 are made of a plurality of active materials, a feature amount corresponding to the charge and discharge characteristics depending on each of the active materials can be calculated from the differential curve. If the feature amount depending on each of the active materials is calculated, the degree of a change in the feature amount corresponding to capacitance degradation is proportional to a degradation rate of the active materials. That is, a feature amount of an active material having a large degradation rate (easy to deteriorate) easily changes. A feature amount of an active material having a small degradation rate (difficult to deteriorate) does not easily change. As in the embodiment, the calculation of a feature amount from the differential curve can allow the feature amount depending on each of the active materials and a change in the feature amount to become understandable. The feature amount calculator 32 inputs the calculated feature amount into the degradation diagnosis processor 4. Also, the measurement result of the inspection device 2 is input into the degradation diagnosis processor 4.

The degradation diagnosis processor 4 diagnoses degradation of the secondary battery 1, such as capacitance degradation, based on the feature amount input by the feature amount calculation device 3. The degradation diagnosis processor 4 includes a degradation characteristic DB (database) 41 to store a degradation characteristic and a degradation diagnoser 42 to diagnose degradation such as capacitance degradation.

The degradation characteristic DB 41 (degradation characteristic storage) stores the degradation characteristic representing a relation between a feature amount and battery performance (degradation) of the secondary battery 1. The battery performance may be, for example, a capacitance value, a resistance value and a capacitance degradation rate. Also, the degradation characteristic DB 41 stores a parameter that is a threshold value used to be compared with the feature amount, thereby making a diagnosis of “unserviceable” or “degradation progress”, as described below. The degradation characteristic can be obtained, as one example, by putting an unused secondary battery 1 to a cycle degradation test or a calendar degradation test. Furthermore, the capacitance degradation rate is a calculated value: [1−(a capacitance value “Q” of a secondary battery 1 to be diagnosed)/(a capacitance value “Q” of the secondary battery 1 when not yet used)] and the larger capacitance degradation rate shows more progress in capacitance degradation. The degradation diagnoser 42 may input information about the feature amount and the performance of the secondary battery 1 to be diagnosed into the degradation characteristic DB 41 and the degradation characteristic DB 41 may make the input information correspond to a type of battery (for example, identify the type by a product name) to store the information. This can allow the content of the information stored in the degradation characteristic DB 41 to be made complete and the diagnostic accuracy to be improved.

The degradation diagnoser 42 diagnoses capacitance degradation of the secondary battery 1 by comparing one or a plurality of the feature amounts input by the feature amount calculation device 3 with the degradation characteristic of each of the feature amounts stored in the degradation characteristic DB. The diagnosis result may be a numerical value (such as a capacitance degradation rate) based on the feature amounts or a discrete rating made by using an arbitrary reference based on the relevant numerical value. As the discrete rating, for example, a 3-stage diagnosis result, such as “unserviceable,” “degradation progress” and “serviceable” may be used. The degradation diagnoser 42 inputs the diagnosis result into the output device 5.

The output device 5 outputs the diagnosis result. The output device 5 may be configured to display the diagnosis result by using a display.

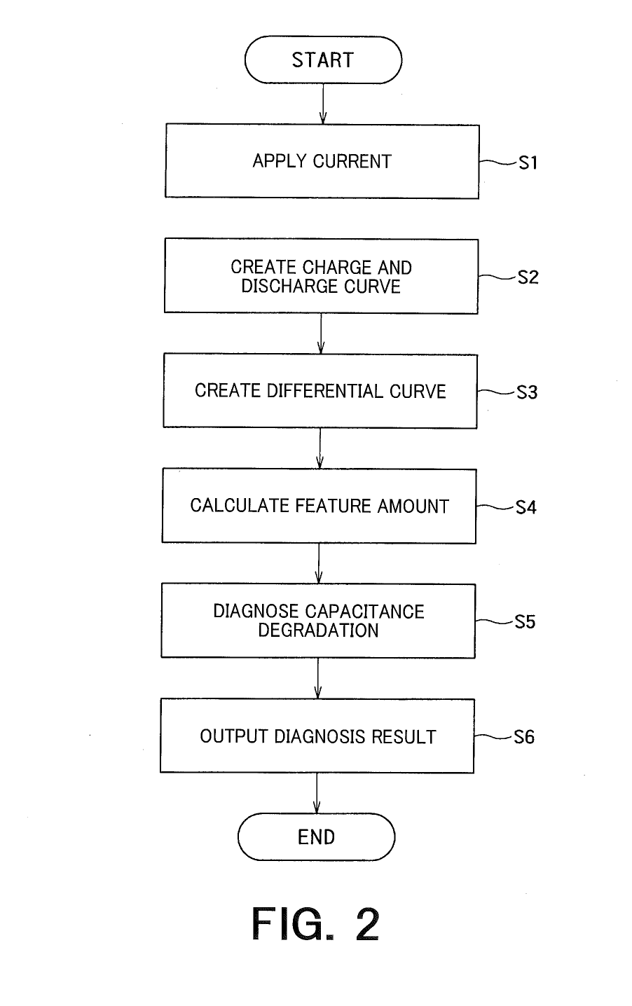

Next, operation of the degradation diagnosis system of this embodiment will be described with reference to FIG. 2 to FIG. 7. Here, FIG. 2 is a flowchart showing the operation of the degradation diagnosis system.

### (Step S1)

First, the inspection device 2, after confirming that a secondary battery 1 to be diagnosed is connected to the inspection device 2, applies a constant current (charge or discharge) to the secondary battery 1. At this time, an onset voltage and an end voltage are predetermined and the current is applied within the range between these. In this embodiment, as the secondary battery 1, a lithium ion secondary battery is used that includes a positive electrode containing lithium manganate (hereafter, called “LMO”) and a Ni—Co—Al oxide composed of nickel, cobalt and aluminum in molar ratio of 72%-18%-10%. Where the secondary battery 1 to be diagnosed is an assembled battery composed of a plurality of cells, a voltage applied to each of the cells is adjusted so that a charge current rate to each of the cells is equal correspondingly to a configuration of the assembled battery.

### (Step S2)

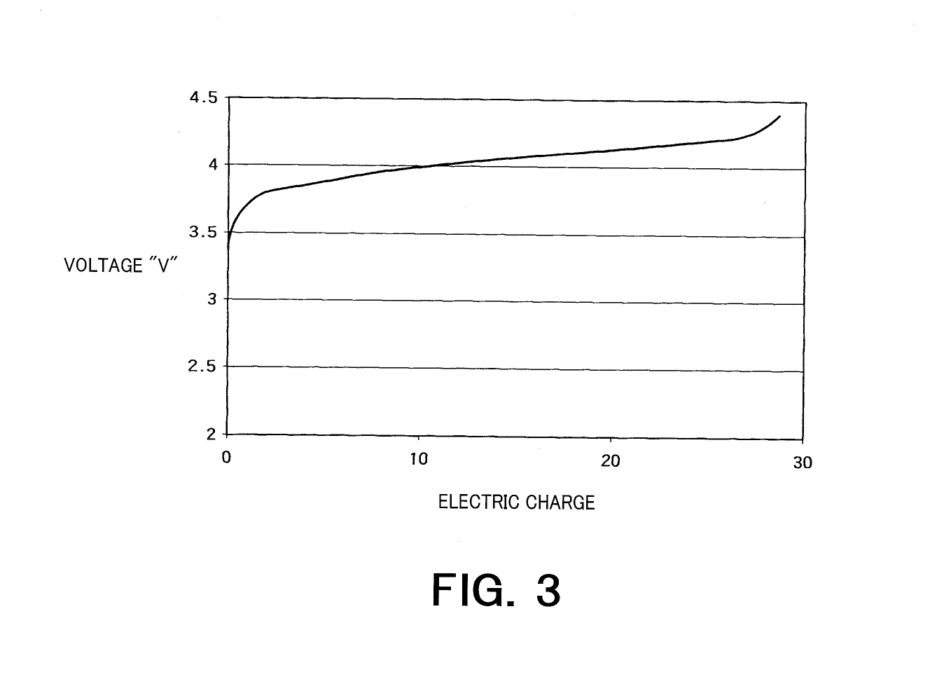

The charge and discharge curve creator 21 of the inspection device 2 creates at least one of a charge curve and a discharge curve, based on charge and discharge characteristics (a voltage “V” between terminals of the secondary battery 1 and an electric charge “Q”) obtained by applying the constant current. FIG. 3 is a graph showing the charge curve created by the charge and discharge curve creator 21. As shown in FIG. 3, for the charge curve, a vertical axis is set to represent the voltage “V” between the terminals of the secondary battery 1, and a horizontal axis is set to represent the electric charge “Q” charged in the secondary battery 1 (i.e., charged energy). The electric charge “Q” is calculated as the product of an applied time of the constant current and the charge current rate. On the horizontal axis, the applied time, instead of the electric charge “Q”, may be used. As capacitance degradation of the secondary battery 1 progresses, an internal resistance of the secondary battery 1 increases, so that the charge curve moves upward as a whole (an increase direction of the voltage “V”). In this case, the charge curve is created by the charge using the constant current, but the discharge curve may be created by the discharge through the constant current.

### (Step S3)

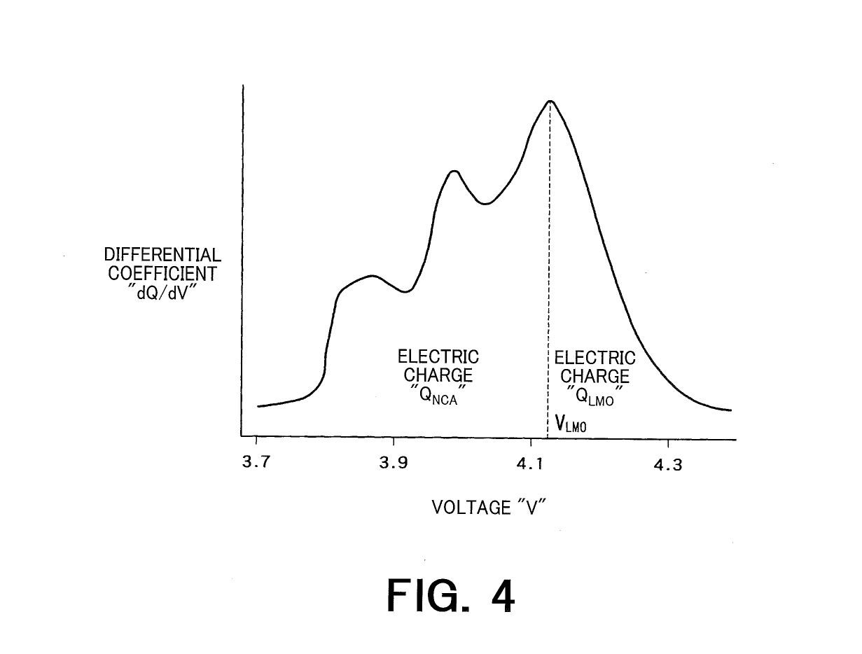

The differential curve creator 22 of the inspection device 2 creates a differential curve representing a relation between a differential coefficient “dQ/dV” showing a slope of the charge curve created in Step S2 and the voltage “V”. FIG. 4 shows the differential curve created from the charge curve in FIG. 3. As shown in FIG. 4, for this differential curve, a horizontal axis is set to represent the differential coefficient “dQ/dV”, and a horizontal axis is set to represent the voltage “V”. In FIG. 4, a plurality of peaks (extremal value) is formed within the range between about 3.7 V and about 4.3 V and outside this range, the differential coefficient “dQ/dV” is nearly constant. The secondary battery differential curve creator 22 inputs the created differential curve into the feature amount calculator 32 of the feature amount calculation device 3.

### (Step S4)

The feature amount calculator 32 calculates a feature amount from the input differential curve with reference to the feature amount identification DB 31. In this embodiment, the feature amount calculator 32 calculates a reference feature amount that has made a small change due to capacitance degradation of the secondary battery 1 and a degradation feature amount that has changed due to the capacitance degradation of the secondary battery 1 more than the reference feature amount, based on a voltage at the extremal value or an inflection point of the differential curve, and calculates a relative feature amount, based on the reference feature amount and the degradation feature amount.

First, the feature amount calculator 32, as one example, acquires a voltage “V_{LMO}” at which the differential curve takes a local maximum value and a maximum value within the voltage range of higher than 4 V. This voltage “V_{LMO}” is a feature amount calculated based on the charge and discharge characteristics of LMO that is an active material for the positive electrode.

Next, the feature amount calculator 32 calculates an electric charge “Q_{LMO}” that is an integrated value of the differential curve within a range of a voltage “V”>the voltage “V_{LMO}” and an electric charge “Q_{NCA}” that is an integrated value of the differential curve within a range of a voltage “V”<the voltage “V_{LMO}”. In this embodiment, the electric charge “Q_{LMO}” is a feature amount calculated based on charge and discharge characteristics of LMO that is an active material for the positive electrode and calculated as an area of the differential curve within the range of the voltage “V”>the voltage “V_{LMO}”. Also, the electric charge “Q_{NCA}” is a feature amount calculated based on charge and discharge characteristics of NCA that is an active material for the positive electrode and calculated as an area of the differential curve within the range of the voltage “V”<the voltage “V_{LMO}”. LMO, the active material for the positive electrode, has a smaller degradation rate than NCA, so that the electric charge “Q_{LMO}” calculated based on the charge and discharge characteristics of LMO makes a smaller change due to capacitance degradation than the electric charge “Q_{NCA}” calculated based on the charge and discharge characteristics of NCA. That is, in this embodiment, the electric charge “Q_{LMO}” is a reference feature amount and the electric charge “Q_{NCA}” is a degradation feature amount. Note that the differential curve is a this example has a feature in which the differential curve moves downward (in the decrease direction of the differential coefficient “dQ/dV”) within the range of not higher than “V_{LMO}” and its shape makes a small change within the range of higher than “V_{LMO}” as the capacitance degradation of the secondary battery 1 progresses.

Furthermore, the feature amount calculator 32 calculates an electric charge ratio “Q_{NCA}/Q_{LMO}”, based on the calculated electric charge “Q_{LMO}” and electric charge “Q_{NCA}”. The electric charge ratio “Q_{NCA}/Q_{LMO}” is a relative feature amount in this embodiment and correlates to a capacitance degradation rate of the secondary battery 1. The feature amount calculator 32 inputs each of the calculated feature amounts into the degradation diagnosis processor 4.

To calculate a feature amount by the feature amount calculator 32, the feature amount identification DB 31 stores an acquisition method of the voltage “V_{LMO}” and a calculation method of the electric charge “Q_{LMO}”, the electric charge “Q_{NCA}” and the electric charge ratio “Q_{NCA}/Q_{LMO}”. Also, the feature amount identification DB 31 may store a range of a voltage or an electric charge in which a change in the differential curve appears due to capacitance degradation. In this case, the feature amount calculator 32 can calculate the electric charge “Q_{LMO}” and the electric charge “Q_{NCA}” within the range of the relevant voltage. Also, the range of the voltage in which the electric charge “Q_{LMO}” and the electric charge Q_{NCA}” are calculated may be an entire range of the voltage in which the charge and discharge curve creator 21 obtained the measurement result. Note that when the charge and discharge curve creator 21 creates the discharge curve, the voltage “V_{LMO}” at which the differential curve takes a local minimum value and a minimum value may be used.

### (Step S5)

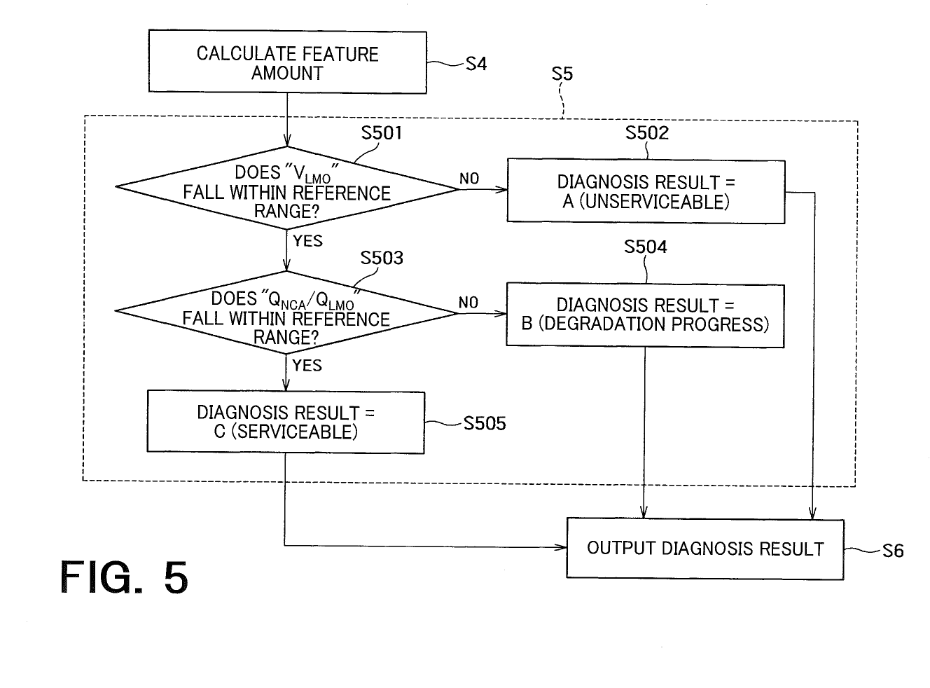

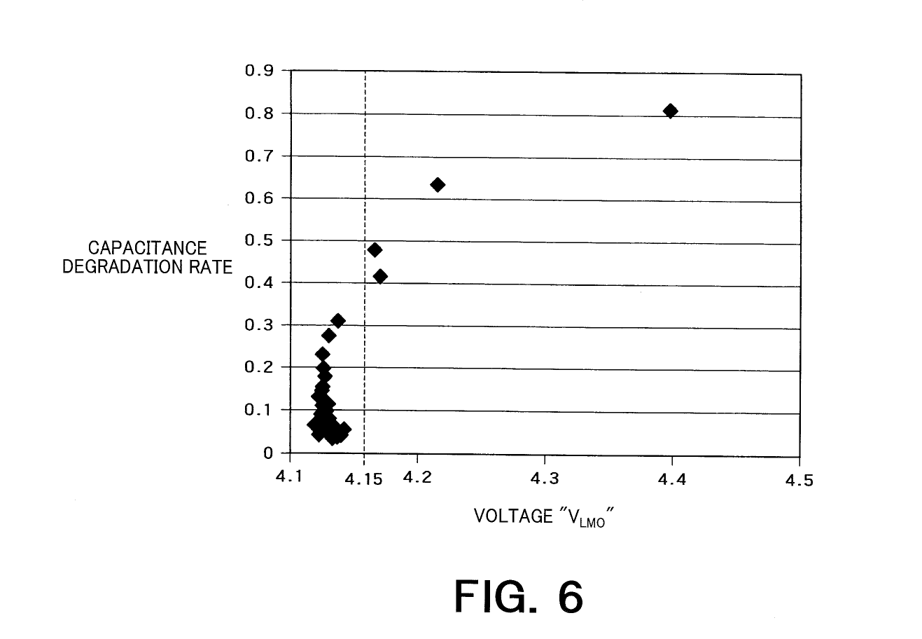

The degradation diagnosis processor 4 diagnoses degradation of the secondary battery 1, based on the input feature amounts. Here, the case of diagnosis of capacitance degradation is shown. FIG. 5 is a process flowchart for a degradation diagnosis in the first embodiment. First, the degradation diagnoser 42 determines whether the voltage “V_{LMO}” falls within the reference range or not by comparing the voltage “V_{LMO}” that is the input feature amount with the degradation characteristic of the voltage “V_{LMO}” stored in the degradation characteristic DB 41 (Step 501). As one example, as shown in FIG. 6, the degradation characteristic of the voltage “V_{LMO}” is represented as a relation between the voltage “V_{LMO}” and the capacitance degradation rate, and the voltage “V_{LMO}” is nearly constant unless the secondary battery 1 deteriorates in the extreme. For example, based on the relevant degradation characteristic, the reference range is preset to be not less than 4.1 V and not greater than 4.15 V, and it is stored in the degradation characteristic DB 41. The degradation diagnoser 42 determines whether the voltage “V_{LMO}” falls within the reference range or not, and if the voltage “V_{LMO}” is outside the reference range, it diagnoses as “unserviceable” (Step 502). According to FIG. 6, if the voltage “V_{LMO}” is outside the reference range, the capacitance degradation rate is equal to or more than about 0.4 (40%) and it is thought an internal resistance increased in the extreme and the degradation has progressed as a whole.

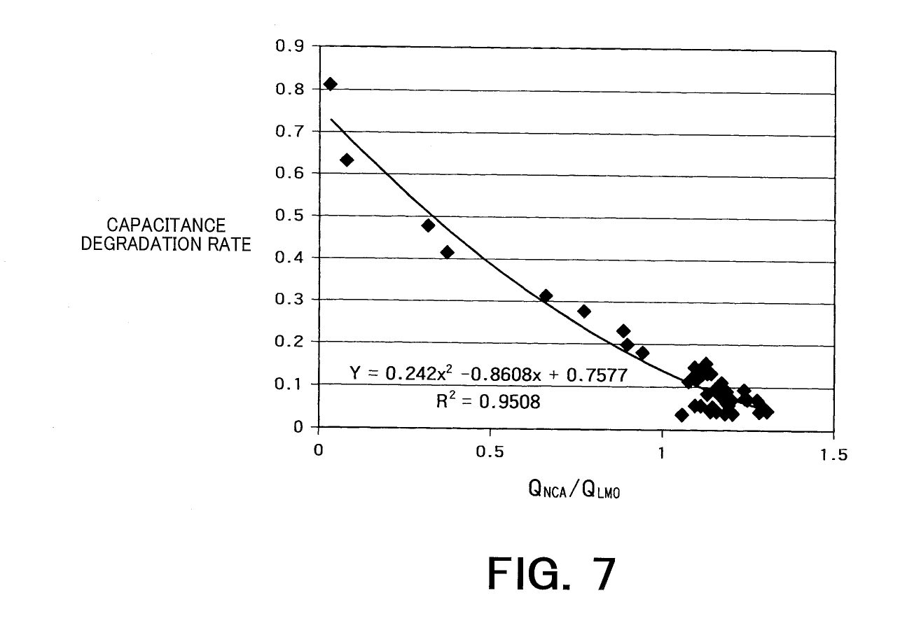

If the voltage “V_{LMO}” is within the reference range, the degradation diagnoser 42 determines whether the electric charge ratio “Q_{NCA}/Q_{LMO}” falls within the reference range or not by comparing the electric charge ratio “Q_{NCA}/Q_{LMO}” that is a relative feature amount with the degradation characteristic of the electric charge ratio “Q_{NCA}/Q_{LMO}” stored in the degradation characteristic DB 41 (Step 503). As one example, as shown in FIG. 7, the degradation characteristic of the electric charge ratio “Q_{NCA}/Q_{LMO}” is represented as a relation between the electric charge ratio “Q_{NCA}/Q_{LMO}” and the capacitance degradation rate, and the electric charge ratio “Q_{NCA}/Q_{LMO}” correlates to the capacitance degradation rate. For example, based on the relevant degradation characteristic, the reference range is preset to be not less than 1.0 and it is stored in the degradation characteristic DB 41. The degradation diagnoser 42 determines whether the electric charge ratio “Q_{NCA}/Q_{LMO}” falls within the reference range or not, and if the electric charge ratio “Q_{NCA}/Q_{LMO}” is outside the reference range, it diagnoses as “degradation progress” (Step 504). According to FIG. 7, if the electric charge ratio “Q_{NCA}/Q_{LMO}” is outside the reference range, the capacitance degradation rate is not less than about 0.2 and it is thought NCA having been selectively deteriorated largely.

If the electric charge ratio “Q_{NCA}/Q_{LMO}” is within the reference range, the degradation diagnoser 42 determines as “serviceable” (Step 505). The determination result is input into the output device 5.

The degradation characteristic used in the degradation diagnosis at Step S5 can be prepared by bringing a new, unused secondary battery 1 to the cycle degradation test or the calendar degradation test. The degradation characteristics in FIG. 6 and FIG. 7 can be obtained by conducting the calendar degradation test where the new secondary battery 1 remains preserved in SoC (State of Charge) of 90% and the cycle degradation test where charge and discharge are repeated in SoC of 0% to 100%. In both tests, let variables be an environmental temperature, an SoC depth and a constant current rate, and SoC was defined from current capacitance values at which an upper limit voltage and a lower limit voltage are reached.

The degradation diagnosis processor 4 may be configured not only to diagnose capacitance degradation, but to predict a prospective capacitance degradation of the secondary battery 1 to be diagnosed. In this case, the degradation characteristic DB 41 preliminarily stores degradation prediction information, such as a usable life and a possible number of times of charge and discharge for the secondary battery 1, associated with the feature amounts or the degradation characteristic. Then, the degradation diagnoser 42 predicts capacitance degradation of the secondary battery 1 with reference to the degradation prediction information corresponding to the feature amount. Such a configuration can quantify the degradation prediction information required to evaluate a residual value of the secondary battery 1 that continues to be used.

Also, the degradation diagnosis processor 4 may include a control method determiner to determine a control method of the secondary battery 1, based on the feature amounts or the diagnosis result. In this case, the degradation characteristic DB 41 preliminarily stores a charge and discharge control method of the secondary battery 1, associated with the feature amounts or the diagnosis result. Alternatively, the charge and discharge control method may be associated with a capacitance degradation rate estimated based on the feature amounts. The control method determiner can determine the charge and discharge control method of the secondary battery 1 with reference to the charge and discharge control method corresponding to the feature amount or the diagnosis result. Note that the control method determiner may be configured separately from the degradation diagnosis processor 4. An example of the charge and discharge control method will be described. A capacitance value of the secondary battery 1 to be diagnosed is estimated by multiplying the capacitance degradation rate estimated in the degradation diagnosis processor 4 by an initial capacitance value. The estimated capacitance value is set as a maximum electric charge in the charge and discharge control, thereby also allowing overcharge and overdischarge to be prevented. Also, in the case of the discrete rating, the charge and discharge control may be carried out without charge depending on the diagnosis result.

### (Step S6)

The output device 5 outputs the diagnosis result. In this embodiment, the diagnosis result is output as a 3-stage rating, but in addition to the diagnosis result, the feature amounts such as the voltage “V_{LMO}”, the electric charge “Q_{LMO}”, the electric charge “Q_{NCA}” and the electric charge ratio “Q_{NCA}/Q_{LMO}” used in a degradation diagnosis, the measurement result of the inspection device 2 and the estimated capacitance degradation rate and the like may be output.

As described above, the degradation diagnosis system according to this embodiment can diagnose degradation of the secondary battery by using a feature amount derived from the result of a single measurement of charge and discharge. Therefore, even if a past use history of the secondary battery to be diagnosed is not known, a current degradation state of the secondary battery is equivalently diagnosed against the degradation characteristic, thereby allowing evaluation of how much margin is left relative to a serviceability limit of the secondary battery.

Note that in this embodiment, the secondary battery 1 to be diagnosed includes the positive electrode composed of the plurality of active materials, and at the time of diagnosis, a feature amount depending on each of the plurality of active materials of the positive electrode is used, but a secondary battery 1 including the negative electrode composed of a plurality of active materials may be a diagnostic object. In this case, a feature amount depending on each of the plurality of active materials of the negative electrode can be calculated and used for a degradation diagnosis. Also, in the case of a positive electrode or a negative electrode composed of a single active material, when a large change and a small change occur in the “dQ/dV” curve because degradation progress of the electrode differs in different places of the electrode, then this embodiment can be similarly applicable.

### Second Embodiment

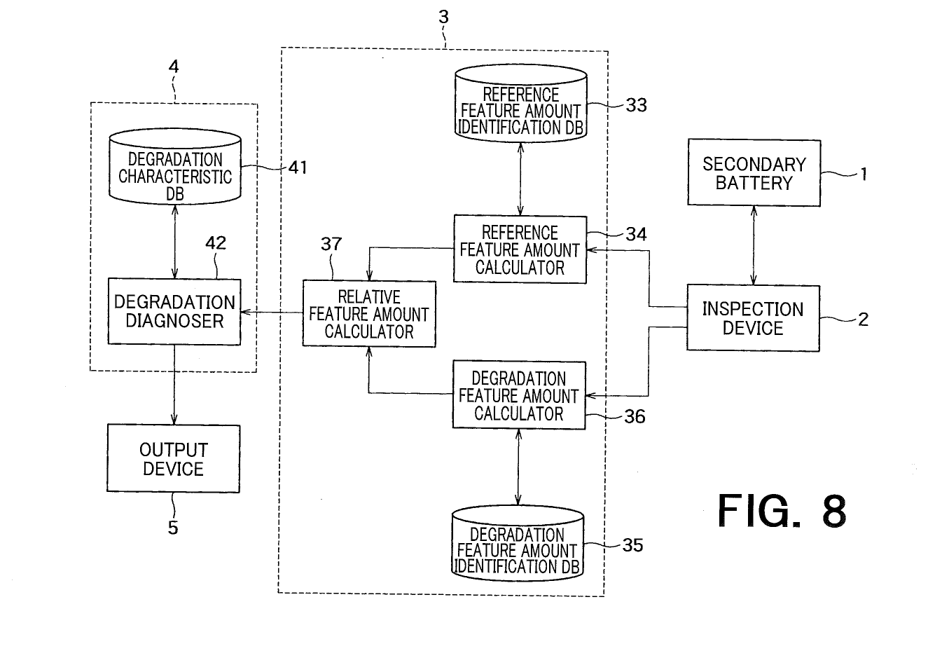

Next, a degradation diagnosis system according to a second embodiment of the invention will be described. In the following, explanation of a common configuration to the first embodiment is omitted and a different configuration is described. FIG. 8 is a block diagram showing the degradation diagnosis system according to the second embodiment.

As shown in FIG. 8, a feature amount calculation device 3 of this embodiment includes a reference feature amount identification DB 33, a reference feature amount calculator 34, a degradation feature amount identification DB 35, a degradation feature amount calculator 36 and a relative feature amount calculator 37. The reference feature amount identification DB 33 and the degradation feature amount identification DB 35 store an algorithm to calculate a reference feature amount and a degradation feature amount, respectively, from information such as a differential curve input by the inspection device 2. Also, the reference feature amount calculator 34 and the degradation feature amount calculator 36 calculate a reference feature amount and a degradation feature amount, respectively, by applying the algorithm obtained from the reference feature amount identification DB 33 and the degradation feature amount identification DB 35, respectively, to the differential curve input by the inspection device 2. The relative feature amount calculator 37 calculates a relative feature amount, based on the reference feature amount calculated by the reference feature amount calculator 34 and the degradation feature amount calculated by the degradation feature amount calculator 36, and outputs it into the degradation diagnosis processor 4.

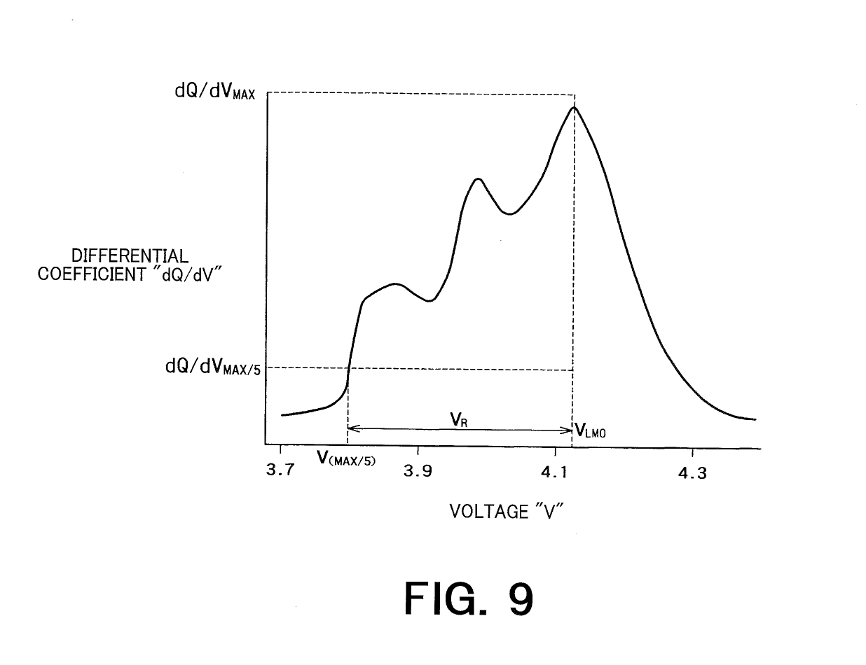

In this embodiment, as the reference feature amount, the voltage “V_{LMO}” described in the first embodiment is used. Also, as the degradation feature amount, as shown in FIG. 9, there is used a voltage “V_{MAX/N}” at which the differential coefficient “dQ/dV” takes 1/N of a value of a differential coefficient “dQ/dV_{MAX}” at the voltage “V_{LMO}”. The parameter “N” may take an arbitrary value not less than 1, preferably not less than 3 and not greater than 20, and in this embodiment, “N”=5. That is, the degradation feature amount in this embodiment is the voltage “V_{MAX/N}”. A voltage “V_{MAX/5}” is a feature amount calculated based on charge and discharge characteristics of NCA that is an active material of the positive electrode and varies largely due to capacitance degradation. Also, the voltage “V_{LMO}”, a reference feature amount, is a feature amount calculated based on charge and discharge characteristics of LMO that is an active material of the positive electrode and makes a small change due to capacitance degradation, as described above.

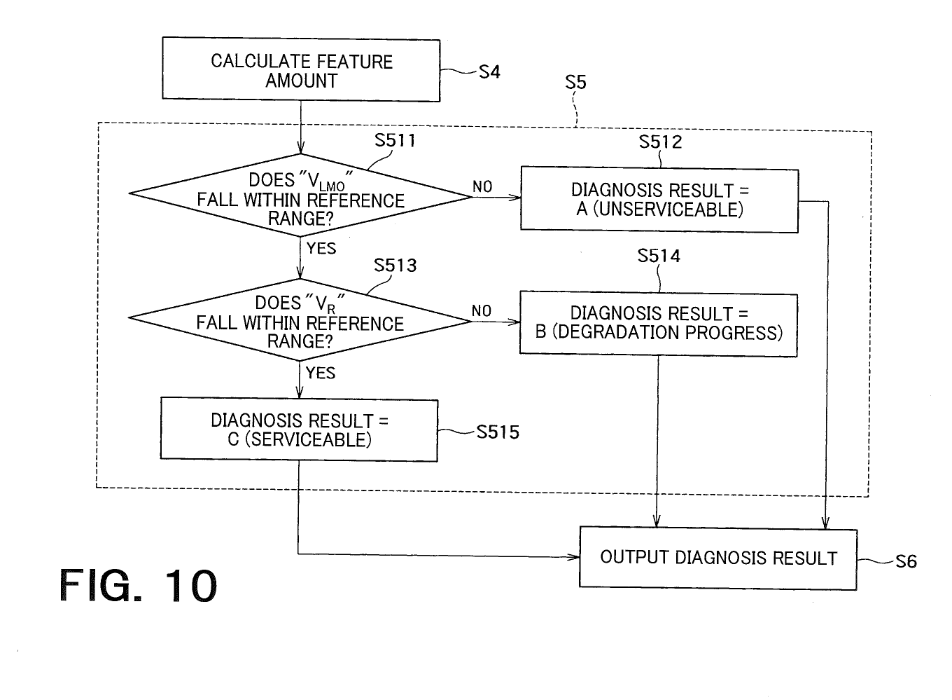

The relative feature amount calculator 37 calculates a voltage “V_{R}” (=V_{LMO}−V_{MAX/5}) that is a relative feature amount, based on the voltage “V_{LMO}” that is a reference feature amount and the voltage “V_{MAX/5}” that is a degradation feature amount. The degradation diagnosis processor 4 diagnoses capacitance degradation of the secondary battery 1, based on the input voltage “V_{R}”. FIG. 10 is a flowchart showing a degradation diagnosis flow of the second embodiment. In this flowchart, Steps S511, 512, 514, 515 are similar to Steps S501, 502, 504, 505 of the first embodiment, respectively. Then, Step S513 will be described.

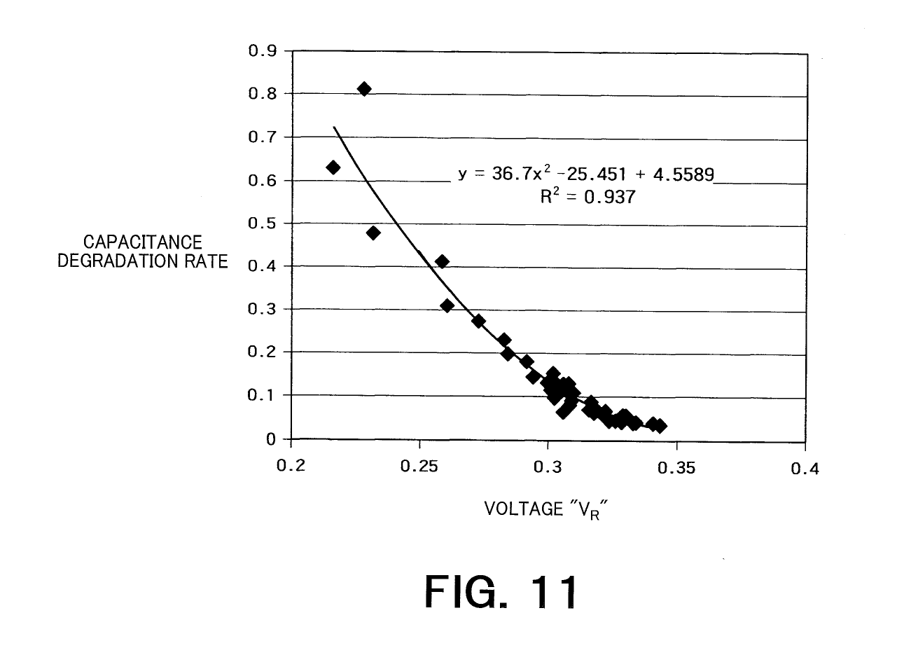

At Step S513, a degradation diagnoser 42 determines whether the voltage “V_{R}” falls within the reference range by comparing the voltage “V_{R}” with a degradation characteristic of the voltage “V_{R}” stored in a degradation characteristic DB 41. As one example, as shown in FIG. 11, the degradation characteristic of the voltage “V_{R}” is represented as a relation between the voltage “V_{R}” and a capacitance degradation rate, and the voltage “V_{R}” correlates to the capacitance degradation rate. The degradation characteristic DB 41 stores a reference range set based on the relevant degradation characteristic. Because the capacitance degradation rate has a high sensitivity to the voltage “V_{R}”, a use of the voltage “V_{R}” can improve the accuracy of a degradation diagnosis. The degradation diagnoser 42 determines the diagnosis result as “degradation progress” if the voltage “V_{R}” is outside the reference range (Step S514). It determines the diagnosis result as “serviceable” if within the reference range (Step S515).

As described above, the degradation diagnosis system according to this embodiment calculates the voltage “V_{MAX/N}” that is the degradation feature amount by using the voltage “V_{LMO}” that is the reference feature amount as the reference. The voltage “V_{MAX/N}” and the voltage “V_{LMO}” are affected by an internal resistance of the secondary battery 1 to the same degree, and the voltage “V_{R}” is not affected by the internal resistance because the voltage “V_{R}” is calculated as a difference between them. A degradation diagnosis is carried out by using such a voltage “V_{R}”, thereby allowing a highly accurate degradation diagnosis with reduction in influence of the internal resistance of the secondary battery 1.

### Third Embodiment

Next, a degradation diagnosis system according to a third embodiment of the invention will be described. A configuration of the degradation diagnosis system of this embodiment is similar to that of the degradation diagnosis system of the first embodiment. In this embodiment, as a feature amount, a voltage is used that is calculated based on a temperature “T” and a width “W” of the secondary battery 1 at the time of charge and discharge.

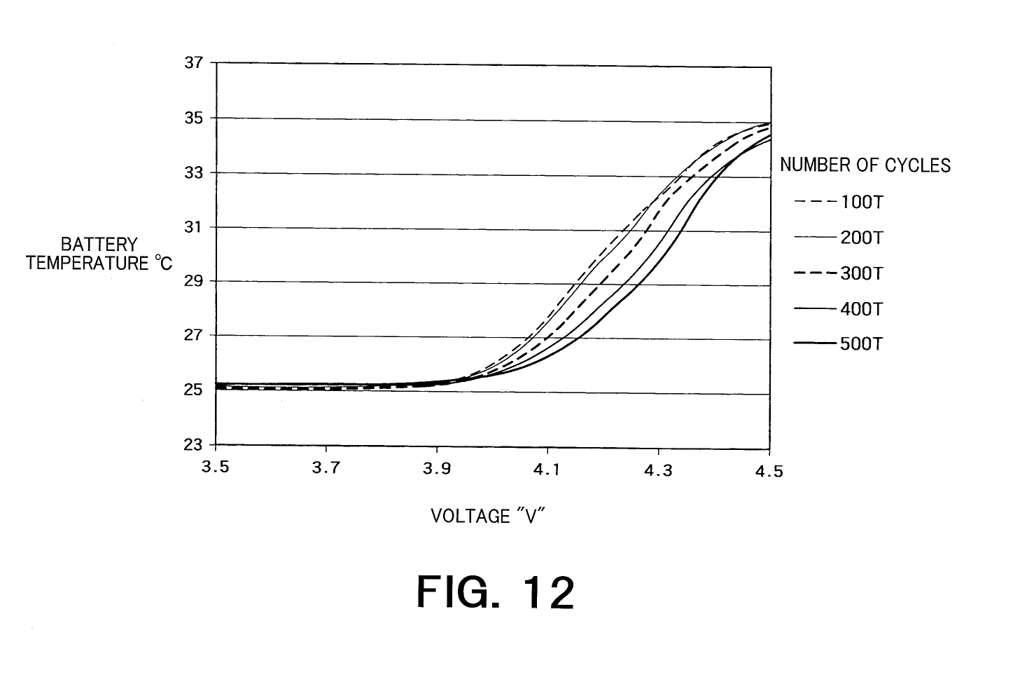

In this embodiment, the inspection device 2 measures the temperature “T” of the secondary battery 1. FIG. 12 is a view showing a relation between a temperature characteristic and capacitance degradation of the secondary battery 1. As shown in FIG. 12, the temperature characteristic of the secondary battery 1 is represented as a relation between a voltage “V” at the time of charge (or at the time of discharge) and the temperature “T” (or a temperature change) of the secondary battery 1. A thermal efficiency of a battery reaction is not 100%, so that a Joule heat occurs at the time of charge and discharge and the temperature of the secondary battery 1 rises. FIG. 12 shows the temperature characteristic obtained from the cycle degradation test, and a curve on the extreme left shows a temperature characteristic of the secondary battery 1 that has been charged and discharged 100 times and then has a small capacitance degradation. As curves shift toward the right, their cycle number are larger, and the curve on the extreme right shows a temperature characteristic of the secondary battery 1 that has been charged and discharged 500 times and then has a large capacitance degradation. That is, in FIG. 12, the curves showing the temperature characteristic shift toward the right as the capacitance degradation progresses. The feature amount can be calculated from such a correlation between the temperature characteristic and the capacitance degradation, and used for a degradation diagnosis. The inspection device 2 inputs the measured temperature characteristic of the secondary battery 1 into the feature amount calculation device 3.

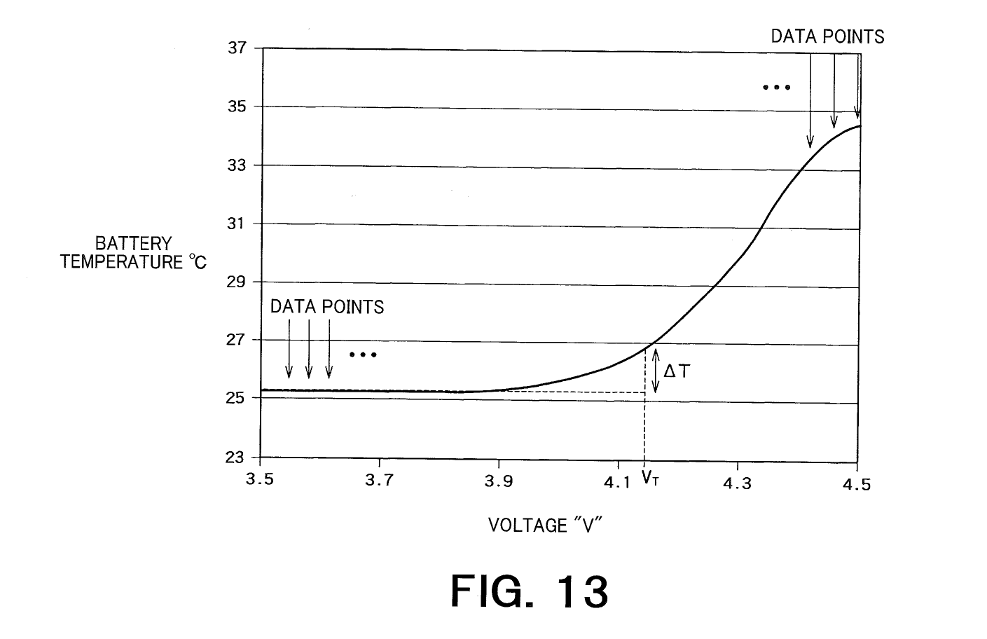

FIG. 13 is a view showing the measured temperature characteristic of the secondary battery 1 by the inspection device. The feature amount calculator 32 calculates a voltage “V_{T}” as a feature amount, based on the input temperature characteristic. The voltage “V_{T}” is a voltage at which the temperature of the secondary battery 1 begins to rise and can be calculated, for example, as a voltage at which the temperature rises from an average temperature of initial 10 data points of the temperature characteristic by a temperature “ΔT” that is 1/10 of a difference between the average temperature of the initial 10 data points and an average temperature of the last 10 data points of the temperature characteristic. Also, a temperature rise amplitude “ΔT” to calculate the voltage “V_{T}” may be a relative value as described above or an absolute value (for example, 1 C.°). Such a calculation method of the voltage “V_{T}” is stored in the feature amount characteristic DB 31. Note that the temperature characteristic may be measured as a relation between the temperature “T” and an electric charge “Q”, and the electric charge “QT” at which the temperature of the secondary battery 1 begins to rise may also be calculated as a feature amount. The calculated voltage “V_{T}” is input into the degradation diagnosis processor 4.

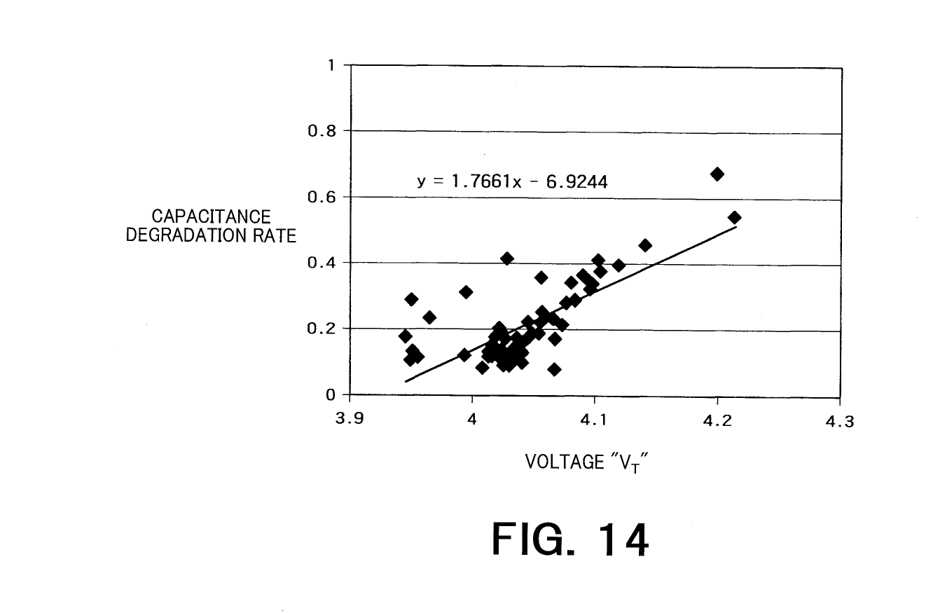

The degradation diagnoser 42 diagnoses capacitance degradation of the secondary battery 1 by comparing the input voltage “V_{T}” with the degradation characteristic of the voltage “V_{T}” stored in the degradation characteristic DB 41. FIG. 14 is a view showing the degradation characteristic of the voltage “V_{T}”. As shown in FIG. 14, a capacitance degradation rate at the voltage “V_{T}” of 4.1 V of the secondary battery 1 is estimated as about 0.3.

In this embodiment, also, the degradation diagnosis system can diagnose capacitance degradation of the secondary battery 1 by measuring a width “W” of the secondary battery 1 at the time of charge and discharge, acquiring a width characteristic represented as a relation between the width “W” and a voltage “V” (or an electric charge “Q”), calculating as a feature amount a voltage “V_{W}” (or “Q_{W}”) that is a voltage (or an electric charge) at which the width “W” begins to increase, and comparing the feature amount with a degradation characteristic of the voltage “V_{W}” (or “Q_{W}”). Because the width “W” of the secondary battery 1 increases and decreases due to charge and discharge, and correlates to capacitance degradation, it can be used for a degradation diagnosis, similarly to the temperature “T” described above.

In the degradation diagnosis using the temperature “T” and the width “W”, as described above, the larger a charge and discharge current rate is at the time of measurement of the temperature “T” and the width “W”, the more sensitivity and accuracy are improved. Therefore, increasing the charge and discharge current rate (for example, made larger than “1 C”) can allow a degradation diagnosis to be carried out at a high speed with a high accuracy. Furthermore, combining such a degradation diagnosis method with the degradation diagnosis methods of the first embodiment and the second embodiment can improve diagnostic accuracy.

### Fourth Embodiment

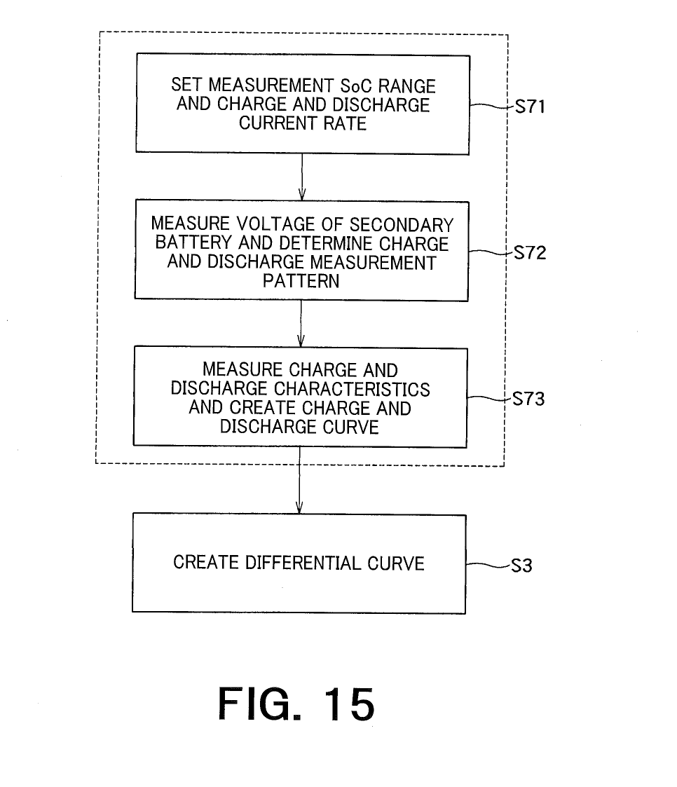

Next, a degradation diagnosis system according to a fourth embodiment of the invention will be described. In this embodiment, a calculation method of a feature amount is similar to those of the above embodiments, but it differs in a creation method of a charge and discharge curve to calculate a feature amount. That is, in this embodiment, the charge and discharge curve creator 21 of the inspection device 2 includes a charge and discharge curve creation DB storing a measurement range (such as a voltage range and a capacitance value range) required to calculate the feature amount, and measures charge and discharge characteristics only within the relevant ranges. Here, FIG. 15 is a process flowchart for the charge and discharge curve creator 21 to create the charge and discharge curve.

### (Step S71)

First, the charge and discharge curve creator 21 sets a measurement SoC range and a charge and discharge current rate of the secondary battery 1 with reference to the charge and discharge curve creation DB. The measurement SoC range is a range of a voltage “V” or an electric charge “Q” in which the charge and discharge curve creator 21 measures the charge and discharge characteristics of the secondary battery 1. The measurement SoC range is preset correspondingly to a type of the secondary battery 1 to be diagnosed and stored in the charge and discharge curve creation DB. The measurement SoC range is set to include a range of a voltage “V” or an electric charge “Q” required to calculate the feature amount. For example, if the voltage “V_{LMO}” in the first embodiment is used as a feature amount, a range of a voltage “V” within the measurement SoC range is set to be a lower limit voltage “V_{LOW}”<the voltage “V_{LMO}”<an upper limit voltage “V_{HIGH}”. Also, a range of an electric charge “Q” within the measurement SoC range is set to be a lower limit electric charge “Q_{LOW}”<an electric charge “Q” within the voltage “V_{LMO}”<an upper limit electric charge “Q_{HIGH}”. If a plurality of feature amounts is used, the measurement SoC range is set to include a range of a voltage “V” or an electric charge “Q” required to calculate the plurality of feature amounts.

The charge and discharge current rate is set for each of the types of the secondary battery, and preliminarily stored in the charge curve creation DB. Because, for each of the types of the secondary battery, there is a current range where it is easy to detect capacitance degradation, the charge and discharge current rate is preset according to the relevant range. As a charge current rate and a discharge current rate for the same type of the secondary battery, the same value may be set, or a different value from each other may be set.

### (Step S72)

Next, the charge and discharge curve creator 21 measures an initial voltage “V_{INI}” or an initial electric charge “Q_{INI}” of the secondary battery 1 at a measurement onset time and determines a charge and discharge measurement pattern. The measurement of the initial voltage “V_{INI}” or the initial electric charge “Q_{INI}” of the secondary battery 1 can be carried out by the existing any methods. Subsequently, the charge and discharge curve creator 21 determines the charge and discharge measurement pattern, based on the measured initial voltage “V_{INI}” or initial electric charge “Q_{INI}” of the secondary battery 1 and the measurement SoC range set at Step S71. The charge and discharge measurement pattern is a pattern by which the charge and discharge curve creator 21 charges or discharges the secondary battery 1 to measure the charge and discharge characteristics of the secondary battery 1, and determined depending on a relation between the set measurement SoC range and the measured initial voltage “V_{INI}” or initial electric charge “Q_{INI}” of the secondary battery 1. In the following, the case where the measurement SoC range is set by the electric charge “Q” (the lower limit electric charge “Q_{LOW}”<the electric charge “Q”<the upper limit electric charge “Q_{HIGH}”) will be described.

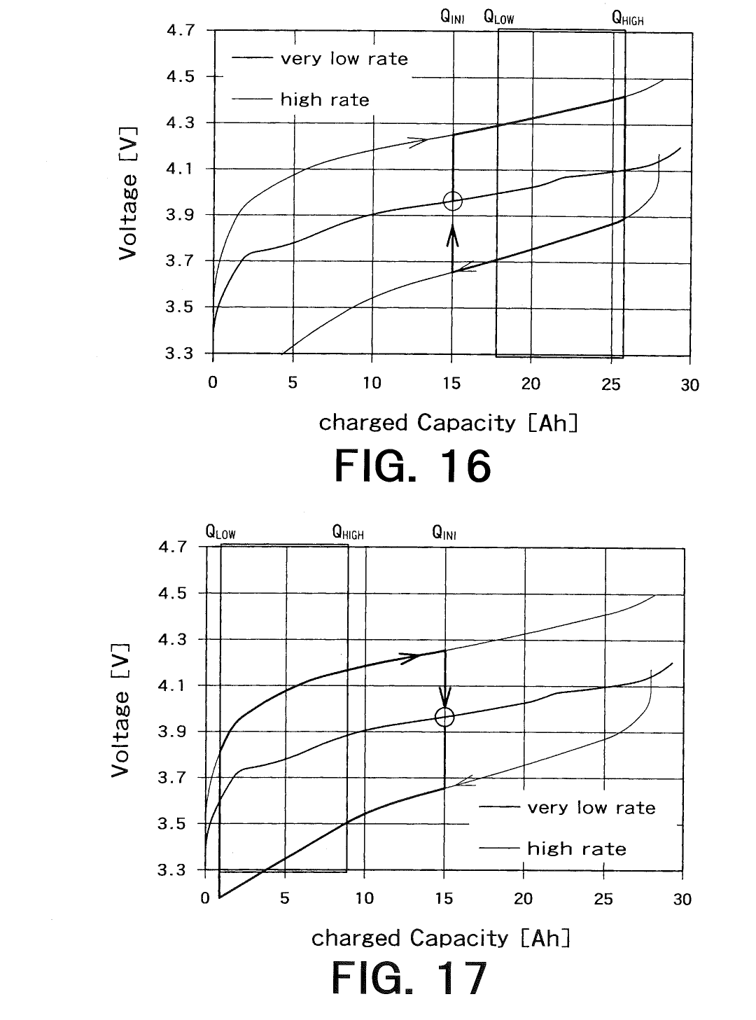

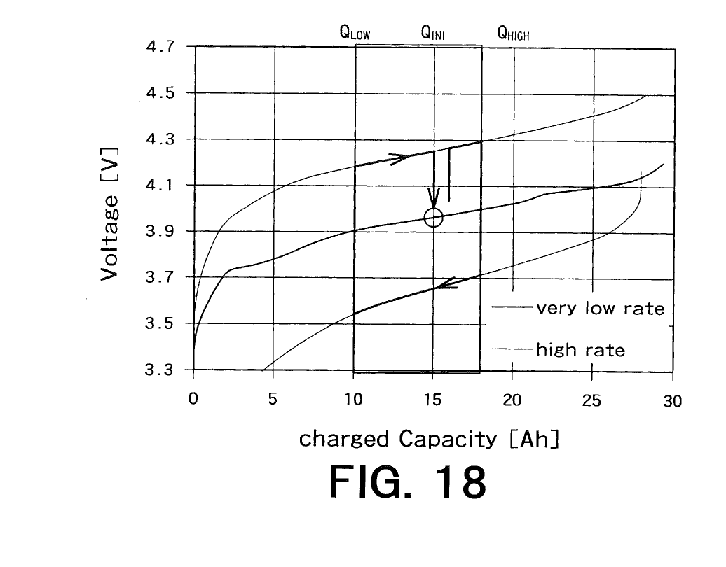

It is considered that there are 3 patterns for the relation between the measurement SoC range and the electric charge “Q_{INI}”. That is, a pattern 1 is the initial electric charge “Q_{INI}”<the lower limit electric charge “Q_{LOW}”, a pattern 2 is the upper limit electric charge “Q_{HIGH}”<the initial electric charge “Q_{INI}” and a pattern 3 is the lower limit electric charge “Q_{LOW}”<the initial electric charge “Q_{INI}”<the upper limit electric charge “Q_{HIGH}”. As shown from the point of view of the voltage, the case of “V_{INI}”<“V_{LOW}” is the pattern 1, the case of “V_{HIGH}”<“V_{INI}” is the pattern 2 and the case of “V_{LOW}”<“V_{INI}”<“V_{HIGH}” is the pattern 3. In the case of the above pattern 1, as one example, as shown in FIG. 16, the charge and discharge measurement pattern is set so that the charge is carried out, starting from the initial electric charge “Q_{INI}” to the upper limit electric charge “Q_{HIGH}” and subsequently the discharge is carried out, starting from the upper limit electric charge “Q_{HIGH}” to the initial electric charge “Q_{INI}”. In the case of the above pattern 2, as one example, as shown in FIG. 17, the charge and discharge measurement pattern is set so that the discharge is carried out, starting from the initial electric charge “Q_{INI}” to the lower limit electric charge “Q_{LOW}” and subsequently the charge is carried out, starting from the lower limit electric charge “Q_{LOW}” to the initial electric charge “Q_{INI}”. In the case of the above pattern 3, as one example, as shown in FIG. 18, the charge and discharge measurement pattern is determined so that the charge is carried out, starting from the initial electric charge “Q_{INI}” to the upper limit electric charge “Q_{HIGH}” and subsequently the discharge is carried out, starting from the upper limit electric charge “Q_{HIGH}” to the lower limit electric charge “Q_{Low}”, furthermore, the charge is carried out, starting from the lower limit electric charge “Q_{LOW}” to the initial electric charge “Q_{INI}”. Alternatively, this pattern is determined so that the discharge is carried out, starting from the initial electric charge “Q_{INI}” to the lower limit electric charge “Q_{LOW}” and subsequently the charge is carried out, starting from the lower limit electric charge “Q_{LOW}” to the upper limit electric charge “Q_{HIGH}”, furthermore, the discharge is carried out, starting from the upper limit electric charge “Q_{HIGH}” to the initial electric charge “Q_{INI}”.

### (Step S73)

The charge and discharge curve creator 21 measures the charge and discharge characteristics of the secondary battery 1 according to the measurement SoC range and the charge and discharge current rate set at Step S71 and the charge and discharge measurement pattern set at Step S72. As shown in FIGS. 16 and 17, in the cases of the charge and discharge measurement pattern according to the patterns 1, 2, because applying voltage polarities at the time of charge and discharge are opposite to each other, so that two kinds of the measurement result are obtained, then capacitance degradation can be determined by using the result of the measurement in a suitable direction for detection when there is the direction (charge or discharge) easy to detect capacitance degradation depending on a material (an active material) of the secondary battery 1. Also, as shown in FIG. 18, in the case of the pattern 3, the initial electric charge “Q_{INI}” is included in the measurement SoC range and two charge and discharge measurement patterns are conceivable. In this case, the charge and discharge measurement pattern easy to detect capacitance degradation may be selected. The charge and discharge curve creator 21 creates a charge and discharge curve, based on the measurement result and the differential curve creator 22 creates a differential curve of the relevant charge and discharge curve (Step S3 in FIG. 2).

According to this embodiment, through the above configuration, capacitance degradation of the secondary battery can be determined by acquiring only the charge and discharge curve within a voltage range or an electric charge range required to calculate a feature amount and peculiar to the secondary battery. Therefore, because it is not necessary to charge and discharge, starting from a discharge stop voltage to a full charge voltage to determine capacitance degradation of the secondary battery, the time required for evaluation can be considerably shortened and degradation of the secondary battery due to measurement can be suppressed.

Furthermore, charge and discharge are repeatedly carried out within the measurement SoC range, so that an electric charge of the secondary battery to be diagnosed does not change before and after the measurement. Therefore, after a cell constituting an assembled battery is extracted and evaluation is made, the relevant cell can be directly returned to the original assembled battery. Similarly, after an assembled battery (battery module) constituting a battery pack is extracted and evaluation is made, the relevant assembled battery can be directly returned to the original battery pack. This can improve maintenance of an assembled battery and a battery pack. Note that the fact that an electric charge is identical before and after the measurement is one example and a difference (error) of not larger than a threshold value or within a constant range may be allowable.

Furthermore, a parameter to evaluate capacitance degradation can be increased by changing a charge and discharge current rate between charge and discharge. This can improve evaluation accuracy of capacitance degradation of the secondary battery.

The system in each embodiment as described above may also be realized using a general-purpose computer device as basic hardware. That is, each function block (or each section) in the system can be realized by causing a processor mounted in the above general-purpose computer device to execute a program. In this case, the system may be realized by installing the above described program in the computer device beforehand or may be realized by storing the program in a storage medium such as a CD-ROM or distributing the above described program over a network and installing this program in the computer device as appropriate. Furthermore, the database in the system may also be realized using a memory device or hard disk incorporated in or externally added to the above described computer device or a storage medium such as CD-R, CD-RW, DVD-RAM, DVD-R as appropriate.

The present invention is not limited to the above described embodiments as they are, and constituent elements can be substantiated with deformation within a range not deviating from the gist thereof in a practical phase. Various inventions can be formed by appropriate combinations of the plurality of constituent elements disclosed in the above described embodiments. For example, some constituent elements can be deleted from all the constituent elements shown in the embodiments, and the elements across the different embodiments can be appropriately combined.

1. A degradation diagnosis system comprising:
a feature amount calculator to read in relational data including a relation between:
a ratio between a variation of a voltage of a secondary battery and a variation of an electric charge of the secondary battery; and
the voltage or the electric charge of the secondary battery,
to identify the voltage or the electric charge in which a relation between the voltage or the electric charge and the ratio satisfies a predefined condition and to calculate a feature amount of the secondary battery by using the identified voltage or the identified electric charge as a reference on basis of the relational data; and
a degradation diagnoser to diagnose degradation of the secondary battery, based on the feature amount,
wherein the feature amount calculator calculates the feature amount, based on a relation between;
an integrated value within a range where a voltage or an electric charge is larger than the identified voltage or the identified electric charge and
an integrated value within a range where the voltage or the electric charge is smaller than the identified voltage or the identified electric charge, in a curve represented by the relational data.

2. A degradation diagnosis system comprising:
a feature amount calculator to read in relational data including a relation between
a ratio of a variation of a voltage of a secondary battery and a variation of an electric charge of the secondary battery and
the voltage or the electric charge of the secondary battery,
to identify the voltage or the electric charge in which a relation between the voltage or the electric charge and the ratio satisfies a predefined condition and to calculate a feature amount of the secondary battery by using the identified voltage or the identified electric charge as a reference on basis of the relational data; and
a degradation diagnoser to diagnose degradation of the secondary battery, based on the feature amount,
wherein the feature amount calculator calculates the feature amount, based on a relation between;
a voltage or an electric charge corresponding to 1/N (“N” has a value of not less than 1) of the ratio corresponding to the identified voltage or the identified electric charge and
the identified voltage or the identified electric charge.

3. The degradation diagnosis system according to claim 1, wherein the voltage satisfying the predefined condition is a voltage at an extremal value or an inflection point of a curve represented by the relational data.

4. The degradation diagnosis system according to claim 1, wherein the degradation diagnoser diagnoses the degradation of the secondary battery by comparing the feature amount with a degradation characteristic representing a relation between the feature amount and the degradation of the secondary battery.

5. The degradation diagnosis system according to claim 1, wherein the degradation diagnoser predicts a prospective degradation of the secondary battery by using degradation prediction information representing a relation between the feature amount and the prospective degradation of the secondary battery.

6. The degradation diagnosis system according to claim 1, further comprising a control method determiner to determine a charge and discharge control method of the secondary battery, based on the feature amount or a diagnosis result of the degradation diagnoser.

7. The degradation diagnosis system according to claim 1, further comprising:
an inspection device to measure a voltage by conducting at least one of charge and discharge of a secondary battery,
a charge and discharge data creator to acquire at least one of charge data and discharge data, based on the measured voltage by the inspection device, and
a relational data creator to create the relational data, based on at least one of the charge data and the discharge data.

8. The degradation diagnosis system according to claim 7, wherein
the inspection device carries out at least one of charge and discharge of the secondary battery within a preliminarily designated range of a voltage or an electric charge, and
the preliminarily designated range is a range not narrower than a range includable of the identified voltage or the identified electric charge and not wider than a range from a discharge stop voltage to a full charge voltage of the secondary battery.

9. The degradation diagnosis system according to claim 8, wherein the inspection device charges and discharges the secondary battery so that a difference between a electric charge of the secondary battery at a measurement onset time and an electric charge of the secondary battery at an end of the measurement is not greater than a threshold value or falls within a constant range.

10. The degradation diagnosis system according to claim 9, wherein the inspection device uses a different charge current rate between charge and discharge of the secondary battery.

11. The degradation diagnosis system according to claim 1, wherein the secondary battery includes one of a positive electrode and a negative electrode, which comprises at least two kinds of active material.

12. A degradation diagnosis system comprising:
a feature quantity calculator to read in measurement data obtained by measuring at least one of a temperature and a width of a secondary battery during a time period when charging or discharging the secondary battery and to calculate a voltage or an electric charge as a feature amount when a variation of at least one of the temperature and the width satisfies a predefined condition, and
a degradation diagnoser to diagnose degradation of the secondary battery, based on the feature amount.

13. A degradation diagnosis method comprising:
reading in relational data including a relation between:
a ratio between a variation of a voltage of a secondary battery and a variation of an electric charge of the secondary battery; and
the voltage or the electric charge of the secondary battery,
identifying the voltage or the electric charge in which a relation between the voltage or the electric charge and the ratio satisfies a predefined condition
calculating a feature amount of the secondary battery by using the identified voltage or the identified electric charge as a reference on basis of the relational data; and
diagnosing degradation of the secondary battery, based on the feature amount,
wherein the calculating a feature amount comprises calculating the feature amount, based on a relation between;
an integrated value within a range where a voltage or an electric charge is larger than the identified voltage or the identified electric charge and
an integrated value within a range where the voltage or the electric charge is smaller than the identified voltage or the identified electric charge, in a curve represented by the relational data.

14. A degradation diagnosis system comprising:
reading in relational data including a relation between:
a ratio between a variation of a voltage of a secondary battery and a variation of an electric charge of the secondary battery; and
the voltage or the electric charge of the secondary battery,
identifying the voltage or the electric charge in which a relation between the voltage or the electric charge and the ratio satisfies a predefined condition
calculating a feature amount of the secondary battery by using the identified voltage or the identified electric charge as a reference on basis of the relational data; and
diagnosing degradation of the secondary battery, based on the feature amount,
wherein the calculating a feature amount comprises calculating the feature amount, based on a relation between;
a voltage or an electric charge corresponding to 1/N (“N” has a value of not less than 1) of the ratio corresponding to the identified voltage or the identified electric charge and
the identified voltage or the identified electric charge.
